(19) United States
(12) Patent Application Publication
(10) Pub. No.: US 2020/0220543 A1
(43) Pub. Date: Jul. 9, 2020

(54) CAPACITIVE TOUCH SENSING CIRCUIT

(71) Applicant: Raydium Semiconductor Corporation, Hsinchu (TW)

(72) Inventors: Chih-Kai CHANG, Keelung City (TW); Chih-Hsiung CHEN, Zhubei City (TW); Yu KUANG, Hsinchu City (TW); Yu-Chin HSU, Hsinchu City (TW)

(21) Appl. No.: 16/734,481

(22) Filed: Jan. 6, 2020

(30) Foreign Application Priority Data
Jan. 8, 2019 (TW) 108100755

(51) Int. Cl. H03K 17/96; G06F 3/044

(52) U.S. Cl. CPC H03K 17/962; H03K 2217/96015; G06F 3/044

(57) ABSTRACT

In a capacitive touch sensing circuit, a parallel capacitor is coupled to a first input terminal and an output terminal of an operational amplifier. A series capacitor and a sensing capacitor are coupled in series between first input terminal and ground. A test capacitor is coupled to a second node and ground. A first switch is coupled to an operating voltage and a first node. A second switch is coupled to first node and ground. A third switch is coupled to second node and ground. A fourth switch is coupled to operating voltage and second node. A first current source and a fifth switch are coupled between operating voltage and first node. A sixth switch and a second current source are coupled between first node and ground. A seventh switch is coupled to second node and a third node. An eighth switch is coupled to the parallel capacitor.

### BACKGROUND OF THE INVENTION

### 1. Field of the Invention

The invention relates to touch sensing; in particular, to a capacitive touch sensing circuit.

### 2. Description of the Prior Art

As shown in FIG. 1, in the self-capacitance touch sensing circuit 1, in the charge phase, the switch S1 is turned off and the switch S2 is turned on, so that one terminal of the sensing capacitor Cb is coupled to the input voltage VIN; in the transfer phase, the switch S2 is turned off and the switch S1 is turned on, so that one terminal of the sensing capacitor Cb is coupled to the switching capacitor circuit 10.

The switching capacitor circuit 10 includes an operational amplifier OP, a parallel capacitor Cop and a switch S3. The parallel capacitor Cop and the switch S3 are coupled in parallel between the first input terminal − and the output terminal J of the operational amplifier OP. The second input terminal + of the operational amplifier OP is coupled to the reference voltage VCM, so that the potential at one terminal of the sensing capacitor Cb becomes the reference voltage VCM. In the case without being touched, the charges stored in the sensing capacitor Cb is transferred to the switching capacitor circuit 10 to output an output voltage Vout as a base output voltage.

Once the capacitance of the sensing capacitor Cb is changed (for example, in the case of being touched), the charges stored in the sensing capacitor Cb increases due to the increasing of the capacitance value in the transfer phase, and the charges stored in the sensing capacitor Cb is transferred to the switching capacitor circuit 10 to output an output voltage Vout′ lower than the base output voltage Vout, and the difference between the output voltage Vout′ and the base output voltage Vout is a sensible potential, and the amount of change is inversely proportional to the parallel capacitor Cop.

The disadvantage of general self-capacitance touch sensing is that when the parallel capacitor Cop becomes smaller, the amount of change in the sensible potential also becomes larger to be easier sensed, but the noise is also relatively amplified. Once the output is saturated due to the noise, even if the sensing capacitor Cb is changed, the output cannot be affected, so that the amount of change in the sensible potential will fail. Therefore, the parallel capacitor Cop usually has a capacitance value of several pF or more, thus a relatively large chip area is occupied, resulting in an inability to effectively reduce the chip area and difficulty in reducing production costs.

### SUMMARY OF THE INVENTION

Therefore, the invention provides a capacitive touch sensing circuit to solve the problems occurred in the prior arts.

An embodiment of the invention is a capacitive touch sensing circuit. In this embodiment, the capacitive touch sensing circuit includes an operational amplifier, a parallel capacitor, a series capacitor, a sensing capacitor, a test capacitor, a first switch, a second switch, a third switch, a fourth switch, a first current source, a second current source, a fifth switch, a sixth switch, a seventh switch and an eighth switch. The operational amplifier has a first input terminal, a second input terminal and an output terminal, and the second input terminal receives a reference voltage. The parallel capacitor is coupled between the first input terminal of the operational amplifier and the output terminal. The series capacitor is coupled between the first input terminal of the operational amplifier and a first node. The sensing capacitor is coupled between the first node and a ground terminal. The test capacitor is coupled between a second node and the ground terminal. The first switch is coupled between an operating voltage and the first node. The second switch is coupled between the first node and the ground terminal. The second switch is coupled between the first node and the ground terminal. The fourth switch is coupled between the operating voltage and the second node. The first current source is coupled to the operating voltage. The second current source is coupled to the ground terminal. The fifth switch is coupled between the first current source and the first node. The sixth switch is coupled between the first node and the second current source. The seventh switch is coupled between the second node and a third node, wherein the third node is disposed between the series capacitor and the first input terminal of the operational amplifier. The eighth switch is coupled in parallel with the parallel capacitor and coupled between the first input terminal of the operational amplifier and the output terminal.

In an embodiment, when the capacitive touch sensing circuit is operated in a first charge phase, the second switch, the third switch and the eighth switch are turned on and the first switch, the fourth switch, the fifth switch, the sixth switch and the seventh switch are turned off, so that the first node and the second node are both coupled to the ground terminal, the second node and the third node are disconnected from each other; the first input terminal and the output terminal of the operational amplifier are coupled to each other, and an output voltage outputted by the output terminal of the operational amplifier is equal to the reference voltage.

In an embodiment, when the capacitive touch sensing circuit is operated in a first transfer phase, the fifth switch and the seventh switch are turned on and the first switch, the second switch, the third switch, the fourth switch, the sixth switch and the eighth switch are turned off; the second node and the third node are coupled to each other; the first current source provides a first base compensation current to the first node, so that the first node has a first voltage.

In an embodiment, the first base compensation current is related to the first voltage, the reference voltage, the series capacitor and the sensing capacitor, and a ratio of the first voltage to the reference voltage is related to a ratio of the test capacitor to the series capacitor.

In an embodiment, when the capacitive touch sensing circuit is operated in a second charge phase, the first switch, the fourth switch and the eighth switch are turned on, and the second switch, the third switch, the fifth switch, the sixth switch and the seventh switch are turned off, so that the first node and the second node are coupled to the operating voltage, and the second node and the third node are disconnected from each other; the first input terminal and the output terminal of the operational amplifier are coupled to each other.

In an embodiment, when the capacitive touch sensing circuit is operated in a second transfer phase, the sixth switch and the seventh switch are turned on and the first switch, the second switch, the third switch, the fourth switch, the fifth switch and the eighth switch are turned off; the second node and the third node are coupled to each other, and the second current source provides a second base compensation current from the first node to the ground terminal, so that the first node has a second voltage.

In an embodiment, the second base compensation current is related to the second voltage, the reference voltage, the operating voltage, the series capacitor and the sensing capacitor, and a ratio of a voltage value obtained by subtracting the second voltage from the operating voltage to the reference voltage is related to a ratio of the test capacitor to the series capacitor.

In an embodiment, when the capacitive touch sensing circuit is operated in a second charge phase, the first switch, the fourth switch and the eighth switch are turned on, and the second switch, the third switch, the fifth switch, the sixth switch and the seventh switch are turned off, so that the first node and the second node are coupled to the operating voltage, the second node and the third node are disconnected from each other; the first input terminal and the output terminal of the operational amplifier are coupled to each other.

In an embodiment, when the capacitive touch sensing circuit is operated in a second transfer phase, the sixth switch and the seventh switch are turned on and the first switch, the second switch, the third switch, the fourth switch, the fifth switch and the eighth switch are turned off; the second node and the third node are coupled to each other, and the second current source provides a second base compensation current from the first node to the ground terminal, so that the first node has a second voltage.

In an embodiment, the second base compensation current is related to the second voltage, the reference voltage, the operating voltage, the series capacitor and the sensing capacitor, and a ratio of a voltage value obtained by subtracting the second voltage from the operating voltage to the reference voltage is related to a ratio of the test capacitor to the series capacitor.

In an embodiment, the second base compensation current is related to the second voltage, the reference voltage, the operating voltage, the series capacitor and the sensing capacitor, and a ratio of a voltage value obtained by subtracting the second voltage from the operating voltage to the reference voltage is related to a ratio of the test capacitor to the series capacitor.

In an embodiment, in a first charge-transfer phase, an output voltage change amount of the output voltage is related to a sensing capacitance change amount of the sensing capacitor, the sensing capacitor, the series capacitor, the parallel capacitor and a first voltage of the first node.

In an embodiment, a ratio of the first voltage to the reference voltage is related to a ratio of the test capacitor to the series capacitor.

In an embodiment, in a second charge-transfer phase, an output voltage change amount of the output voltage is related to a sensing capacitance change amount of the sensing capacitor, the sensing capacitor, the series capacitor, the parallel capacitor and a voltage value obtained by subtracting a second voltage of the first node from the operating voltage.

In an embodiment, a ratio of the voltage value subtracting the second voltage from the operating voltage to the reference voltage is related to a ratio of the test capacitor to the series capacitor.

Compared to the prior art, the capacitive touch sensing circuit of the invention can effectively reduce the required capacitance value of the parallel capacitor (Cop) by disposing the series capacitor (Cs) and the test capacitor (Ct) inside the capacitive touch sensing circuit to effectively achieve the effects of reducing the chip area and the production costs. It has the following advantages:

(1) The sensing change amount can be increased.

(2) A combination of a series capacitor (Cs), a test capacitor (Ct) and a parallel capacitor (Cop) having a small capacitance value can achieve the same sensing change amount as the parallel capacitor (Cop) in the conventional capacitive touch sensing circuit.

(3) The ability to suppress noise can be enhanced.

The advantage and spirit of the invention may be understood by the following detailed descriptions together with the appended drawings.

### BRIEF DESCRIPTION OF THE APPENDED DRAWINGS

FIG. 1 is a schematic diagram of the conventional self-capacitance touch sensing circuit 1 in the prior art.

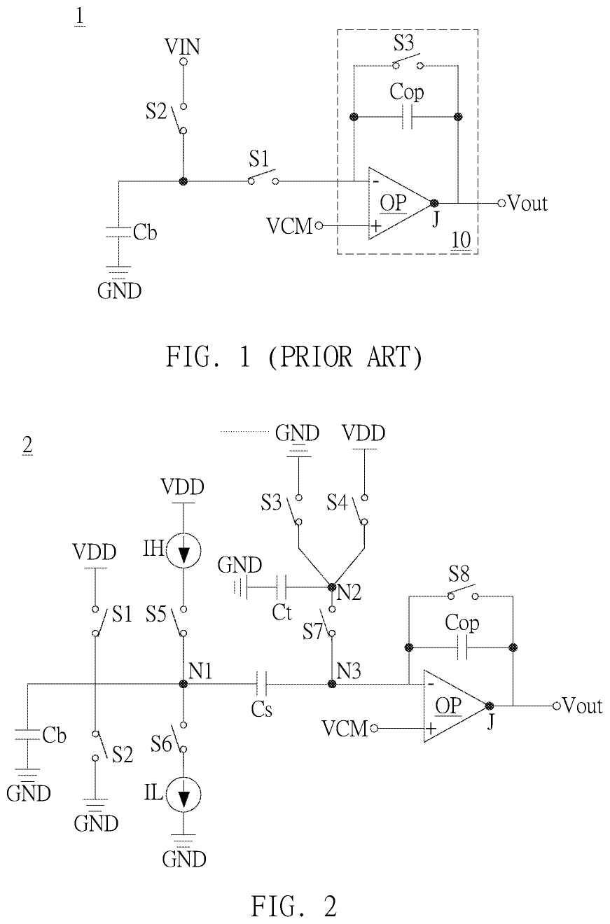

FIG. 2 is a schematic diagram of the self-capacitance touch sensing circuit in an embodiment of the invention.

FIG. 3A to FIG. 3D illustrate schematic diagrams of the capacitive touch sensing circuit operated in a first charge phase H, a first transfer phase H, a second charge phase L and the second transfer phase L respectively.

FIG. 4 illustrates a simulation schematic diagram of the capacitive touch sensing circuit 4 when the capacitance of the sensing capacitor Cop=100 p, the capacitance of the series capacitor Cs=0.2 p, the capacitance of the test capacitor Ct=0.28 p, the capacitance of the parallel capacitor Cop=0.15 p, and the resistance of the resistor R=2 k.

FIG. 5 illustrates a timing diagram illustrating an output voltage change amount of 12.7 mV which is simulated and detected by the capacitive touch sensing circuit 4 of FIG. 4.

### DETAILED DESCRIPTION OF THE INVENTION

An embodiment of the invention is a capacitive touch sensing circuit. In this embodiment, the capacitive touch sensing circuit is a self-capacitance touch sensing circuit, but not limited to this.

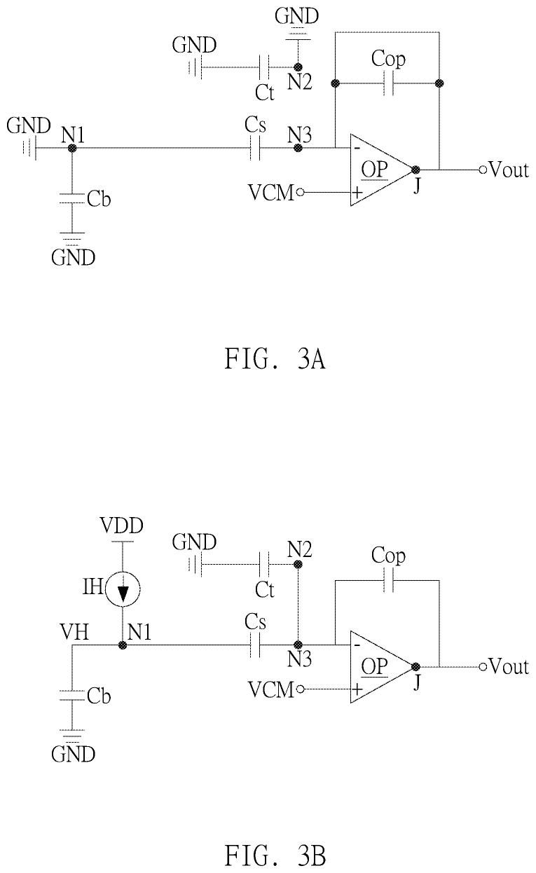

Please refer to FIG. 2. FIG. 2 is a schematic diagram of the capacitive touch sensing circuit 2 in this embodiment.

As shown in FIG. 2, the capacitive touch sensing circuit 2 can include an operational amplifier OP, a parallel capacitor Cop, a series capacitor Cs, a sensing capacitor Cb, a test capacitor Ct, a first switch S1, a second switch S2, a third switch S3, a fourth switch S4, a first current source IH, a second current source IL, a fifth switch S5, a sixth switch S6, a seventh switch S7 and an eighth switch S8.

The operational amplifier OP has a first input terminal −, a second input terminal + and an output terminal J. Wherein, the first input terminal − is coupled to the series capacitor Cs; the second input terminal + receives the reference voltage VCM. The parallel capacitor Cop is coupled between the first input terminal − and the output terminal J of the operational amplifier OP.

The series capacitor Cs is coupled between the first input terminal − of the operational amplifier OP and the first node N1. The sensing capacitor Cb is coupled between the first node N1 and the ground terminal GND. The test capacitor Ct is coupled between the second node N2 and the ground terminal GND.

The first current source IH is coupled between the operating voltage VDD and the fifth switch S5. The second current source IL is coupled between the sixth switch S6 and the ground terminal GND.

The first switch S1 is coupled between the operating voltage VDD and the first node N1. The second switch S2 is coupled between the first node N1 and the ground terminal GND. The third switch S3 is coupled between the ground terminal GND and the second node N2. The fourth switch S4 is coupled between the operating voltage VDD and the second node N2.

The fifth switch S5 is coupled between the first current source IH and the first node N1. The sixth switch S6 is coupled between the first node N1 and the second current source IL. The seventh switch S7 is coupled between the second node N2 and the third node N3. The third node N3 is disposed between the series capacitor Cs and the first input terminal − of the operational amplifier OP. The eighth switch S8 is coupled in parallel with the parallel capacitor Cop and the eighth switch S8 is also coupled between the first input terminal − and the output terminal J of the operational amplifier OP.

It should be noted that the capacitive touch sensing circuit 2 of the invention can be operated in the following four phases by controlling turn-on or turn-off of the first switch S1 to the eighth switch S8 respectively: a first charge phase H, a first transfer phase H, a second charge phase L and a second transfer phase L.

In practical applications, the capacitive touch sensing circuit 2 can be operated in the first charge phase H and the first transfer phase H to complete touch sensing; the capacitive touch sensing circuit 2 can be operated in the second charge phase L and the second transfer phase L to complete touch sensing; the capacitive touch sensing circuit 2 can also be used in conjunction with the first charge Phase H, the first transfer phase H, the second charge phase L and the second transfer phase L to complete touch sensing to achieve the effect of suppressing noise.

Next, examples showing that the capacitive touch sensing circuit 2 is operated in the four different phases will be described respectively as follows.

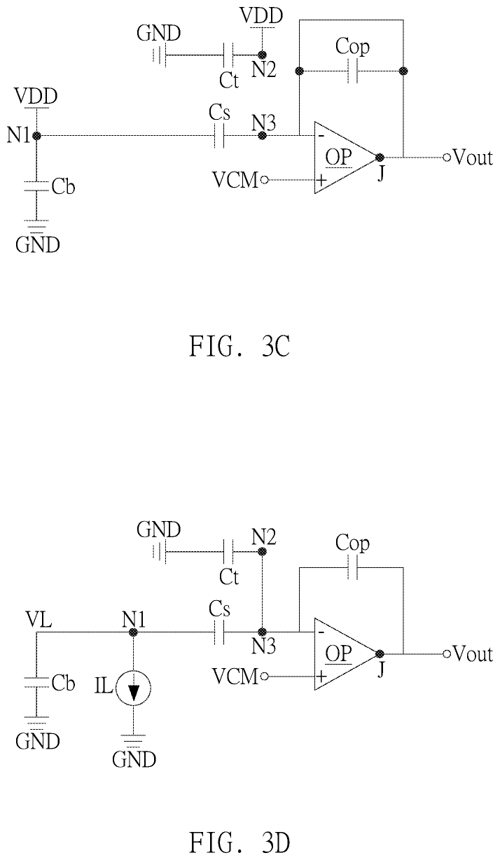

Please refer to FIG. 3A to FIG. 3D. FIG. 3A to FIG. 3D illustrate the capacitive touch sensing circuit 2 operated in the first charge phase H, the first transfer phase H, the second charge phase L and the second transfer phase L. It should be noted that FIG. 3A to FIG. 3D only show the turned-on switches and the turned-off switches are omitted and not shown.

As shown in FIG. 3A, when the capacitive touch sensing circuit 2 is operated in the first charge phase H, the capacitive touch sensing circuit 2 controls the second switch S2, the third switch S3 and The eighth switch S8 to be turned on and the first switch S1, the fourth switch S4, the fifth switch S5, the sixth switch S6 and the seventh switch S7 to be turned off. At this time, the first node N1 and the second node N2 are both coupled to the ground terminal GND, and the second node N2 and the third node N3 are disconnected from each other; the first input terminal − and the output terminal J of the operational amplifier OP are coupled. The output voltage Vout outputted by the output terminal J of the operational amplifier OP is equal to the reference voltage VCM.

As shown in FIG. 3B, when the capacitive touch sensing circuit 2 is operated in the first transfer phase H, the capacitive touch sensing circuit 2 controls the fifth switch S5 and the seventh switch S7 to be turned on and the first switch S1, the second switch S2, the third switch S3, the fourth switch S4, the sixth switch S6 and the eighth switch S8 to be turned off. At this time, the second node N2 and the third node N3 are coupled, and the first current source IH provides a first base compensation current to the first node N1, so that the first node N1 has the first voltage VH.

In practical applications, the first base compensation current provided by the first current source IH is related to the first voltage VH, the reference voltage VCM, the series capacitor Cs and the sensing capacitor Cb, and the ratio of the first voltage VH to the reference voltage VCM is related to the ratio N of the test capacitor Ct to the series capacitor Cs, such as VH/VCM=Ct/Cs=N, but not limited to this.

For example, assuming that the capacitive touch sensing circuit 2 is operated in the first transfer phase during a period of time T, then the first base compensation current provided by the first current source IH can be equal to [(VH−VCM)*Cs+VH*Cb]/T, but not limited to this.

As shown in FIG. 3C, when the capacitive touch sensing circuit 2 is operated in the second charge phase L, the capacitive touch sensing circuit 2 controls the first switch S1, the fourth switch S4 and the eighth switch S8 to be turned on and the second switch S2, the third switch S3, the fifth switch S5, the sixth switch S6 and the seventh switch S7 to be turned off. At this time, the first node N1 and the second node N2 are both coupled to the operating voltage VDD, the second node N2 and the third node N3 are disconnected from each other; the first input terminal − and the output terminal J of the operational amplifier OP are coupled, and the output voltage Vout outputted by the output terminal J of the operational amplifier OP is equal to the reference voltage VCM.

As shown in FIG. 3D, when the capacitive touch sensing circuit 2 is operated in the second transfer phase L, the capacitive touch sensing circuit 2 controls the sixth switch S6 and the seventh switch S7 to be turned on and controls the first switch S1, the second switch S2, the third switch S3, the fourth switch S4, the fifth switch S5 and the eighth switch S8 to be turned off. At this time, the second node N2 and the third node N3 are coupled to each other, and the second current source IL provides a second base compensation current from the first node N1 to the ground terminal GND, so that the first node N1 has the second voltage VL.

In practical applications, the second reference compensation current provided by the second current source IL is related to the second voltage VL, the reference voltage VCM, the operating voltage VDD, the series capacitor Cs and the sensing capacitor Cb, and the ratio of the voltage value obtained by subtracting the second voltage VL from the operating voltage VDD to the reference voltage VCM is related to the ratio (N) of the test capacitor Ct to the series capacitor Cs, such as (VDD−VL)/VCM=Ct/Cs=N, but not limited to this.

For example, assuming that the capacitive touch sensing circuit 2 is operated in the second transfer phase during a period of time T, the second base compensation current provided by the second current source IL can be equal to [(VCM−VL)*Cs+(VDD−VL)*Cb]/T, but not limited to this.

It can be known from the foregoing that when the capacitive touch sensing circuit 2 is switched from the first charge phase H to the first transfer phase H, the first base compensation current provided by the first current source IH can be obtained; when the capacitive touch sensing circuit 2 is switched from the second charge phase L to the second transfer phase L, the second base compensation current provided by the second current source IL can be obtained.

In practical applications, if the sensing capacitor Cb is changed, the output voltage Vout outputted by the output terminal J of the operational amplifier OP will be also changed accordingly.

If the first charge-transfer phase (that is, the first charge phase and the first transfer phase) is taken as an example, assuming that the sensing capacitance change amount of the sensing capacitor Cb is ΔCb, the output voltage change amount ΔVout of the output voltage Vout in the first charge-transfer phase is related to the amount of change in the sensing capacitor ΔCb of the sensing capacitor Cb, the sensing capacitor Cb, the series capacitor Cs, the parallel capacitor Cop and the first voltage VH of the first node N1, but not limited to this. For example, the output voltage change amount ΔVout can be expressed by the following Equation 1:

ΔVout=[ΔCb/(Cb+Cs)]*VH*(Cs/Cop) Equation 1

From Equation 1, it can be known that the output voltage change amount ΔVout in the first charge-transfer phase is directly proportional to the first voltage VH, proportional to the ratio of the series capacitor Cs to the parallel capacitor Cop and inversely proportional to the sensing capacitance Cb.

In addition, the ratio of the first voltage VH to the reference voltage VCM is related to the ratio (N) of the capacitance of the test capacitor Ct to the capacitance of the series capacitor Cs, so that the first voltage VH can be increased up to the operating voltage VDD by adjusting the ratio (N) of the test capacitor Ct to the series capacitor Cs, so that the output voltage change amount ΔVout can be increased, but not limited to this.

If the second charge-transfer phase (that is, the second charge phase and the second transfer phase) is taken as an example, the output voltage change amount ΔVout of the output voltage Vout in the second charge-transfer phase is related to the sensing capacitance change amount ΔCb of the sensing capacitor Cb, the sensing capacitor Cb, the series capacitor Cs, the parallel capacitor Cop and the voltage value obtained by subtracting the second voltage VL of the first node N1 from the operating voltage VDD. For example, the output voltage change amount ΔVout can be expressed by the following Equation 2:

ΔVout=[ΔCb/(Cb+Cs)]*(VDD−VL)*(Cs/Cop) Equation 2

It can be known from Equation 2 that the output voltage change amount ΔVout in the second charge-transfer phase is proportional to the voltage value obtained by subtracting the second voltage VL from the operating voltage VDD, proportional to the ratio of the capacitance of the series capacitor Cs to the capacitance of the parallel capacitor Cop, but inversely proportional to the capacitance of the sensing capacitor Cb.

In addition, the ratio of the voltage value obtained by subtracting the second voltage VL from the operating voltage VDD to the reference voltage VCM is related to the ratio (N) of the capacitance of the test capacitor Ct to the capacitance of the series capacitor Cs. Therefore, the ratio (N) of the test capacitor Ct to the series capacitor can be adjusted to reduce the second voltage VL, so that the voltage value obtained by subtracting the second voltage VL from the operating voltage VDD will be increased to increase the output voltage change amount ΔVout, but not limited to this.

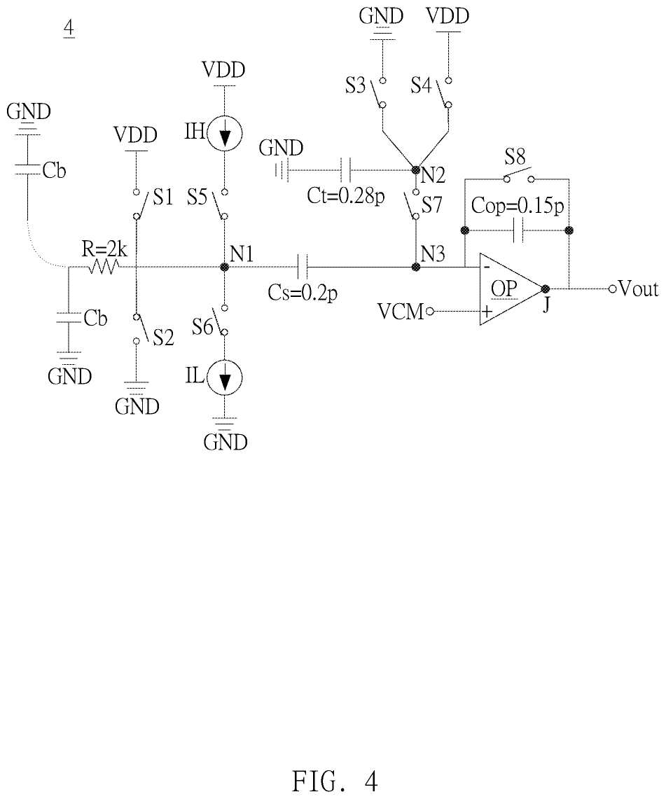

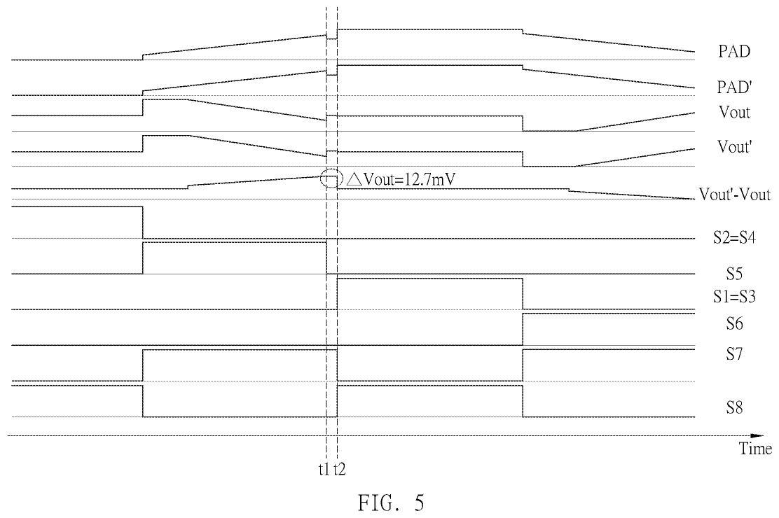

Next, please refer to FIG. 4 and FIG. 5. Assume that the capacitance of the sensing capacitor Cop=100 p, the capacitance of the series capacitor Cs=0.2 p, the capacitance of the test capacitor Ct=0.28 p, the capacitance of the parallel capacitor Cop=0.15 p and the resistance of the resistor R=2 k in the capacitive touch sensing circuit 4 of FIG. 4. As shown in FIG. 5, after the simulation is done, the output voltage change amount ΔVout sensed by the capacitive touch sensing circuit 4=(Vout′−Vout)=12.7 mV, but not limited to this.

Compared to the prior art, the capacitive touch sensing circuit of the invention can effectively reduce the required capacitance value of the parallel capacitor (Cop) by disposing the series capacitor (Cs) and the test capacitor (Ct) inside the capacitive touch sensing circuit to effectively achieve the effects of reducing the chip area and the production costs. It has the following advantages:

(1) The sensing change amount can be increased.

(2) A combination of a series capacitor (Cs), a test capacitor (Ct) and a parallel capacitor (Cop) having a small capacitance value can achieve the same sensing change amount as the parallel capacitor (Cop) in the conventional capacitive touch sensing circuit.

(3) The ability to suppress noise can be enhanced.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A capacitive touch sensing circuit, comprising:
an operational amplifier having a first input terminal, a second input terminal and an output terminal, the second input terminal receiving a reference voltage;
a parallel capacitor, coupled between the first input terminal of the operational amplifier and the output terminal;
a series capacitor, coupled between the first input terminal of the operational amplifier and a first node;
a sensing capacitor, coupled between the first node and a ground terminal;
a test capacitor, coupled between a second node and the ground terminal;
a first switch, coupled between an operating voltage and the first node;
a second switch, coupled between the first node and the ground terminal;
a third switch, coupled between the ground terminal and the second node;
a fourth switch, coupled between the operating voltage and the second node;
a first current source, coupled to the operating voltage;
a second current source, coupled to the ground terminal;
a fifth switch, coupled between the first current source and the first node;
a sixth switch, coupled between the first node and the second current source;
a seventh switch, coupled between the second node and a third node, wherein the third node is disposed between the series capacitor and the first input terminal of the operational amplifier; and
an eighth switch, coupled in parallel with the parallel capacitor and coupled between the first input terminal of the operational amplifier and the output terminal.

2. The capacitive touch sensing circuit of claim 1, wherein when the capacitive touch sensing circuit is operated in a first charge phase, the second switch, the third switch and the eighth switch are turned on and the first switch, the fourth switch, the fifth switch, the sixth switch and the seventh switch are turned off, so that the first node and the second node are both coupled to the ground terminal, the second node and the third node are disconnected from each other; the first input terminal and the output terminal of the operational amplifier are coupled to each other, and an output voltage outputted by the output terminal of the operational amplifier is equal to the reference voltage.

3. The capacitive touch sensing circuit of claim 2, wherein when the capacitive touch sensing circuit is operated in a first transfer phase, the fifth switch and the seventh switch are turned on and the first switch, the second switch, the third switch, the fourth switch, the sixth switch and the eighth switch are turned off; the second node and the third node are coupled to each other; the first current source provides a first base compensation current to the first node, so that the first node has a first voltage.

4. The capacitive touch sensing circuit of claim 3, wherein the first base compensation current is related to the first voltage, the reference voltage, the series capacitor and the sensing capacitor, and a ratio of the first voltage to the reference voltage is related to a ratio of the test capacitor to the series capacitor.

5. The capacitive touch sensing circuit of claim 1, wherein when the capacitive touch sensing circuit is operated in a second charge phase, the first switch, the fourth switch and the eighth switch are turned on, and the second switch, the third switch, the fifth switch, the sixth switch and the seventh switch are turned off, so that the first node and the second node are coupled to the operating voltage, and the second node and the third node are disconnected from each other; the first input terminal and the output terminal of the operational amplifier are coupled to each other.

6. The capacitive touch sensing circuit of claim 5, wherein when the capacitive touch sensing circuit is operated in a second transfer phase, the sixth switch and the seventh switch are turned on and the first switch, the second switch, the third switch, the fourth switch, the fifth switch and the eighth switch are turned off; the second node and the third node are coupled to each other, and the second current source provides a second base compensation current from the first node to the ground terminal, so that the first node has a second voltage.

7. The capacitive touch sensing circuit of claim 6, wherein the second base compensation current is related to the second voltage, the reference voltage, the operating voltage, the series capacitor and the sensing capacitor, and a ratio of a voltage value obtained by subtracting the second voltage from the operating voltage to the reference voltage is related to a ratio of the test capacitor to the series capacitor.

8. The capacitive touch sensing circuit of claim 4, wherein when the capacitive touch sensing circuit is operated in a second charge phase, the first switch, the fourth switch and the eighth switch are turned on, and the second switch, the third switch, the fifth switch, the sixth switch and the seventh switch are turned off, so that the first node and the second node are coupled to the operating voltage, the second node and the third node are disconnected from each other; the first input terminal and the output terminal of the operational amplifier are coupled to each other.

9. The capacitive touch sensing circuit of claim 8, wherein when the capacitive touch sensing circuit is operated in a second transfer phase, the sixth switch and the seventh switch are turned on and the first switch, the second switch, the third switch, the fourth switch, the fifth switch and the eighth switch are turned off; the second node and the third node are coupled to each other, and the second current source provides a second base compensation current from the first node to the ground terminal, so that the first node has a second voltage.

10. The capacitive touch sensing circuit of claim 9, wherein the second base compensation current is related to the second voltage, the reference voltage, the operating voltage, the series capacitor and the sensing capacitor, and a ratio of a voltage value obtained by subtracting the second voltage from the operating voltage to the reference voltage is related to a ratio of the test capacitor to the series capacitor.

11. The capacitive touch sensing circuit of claim 1, wherein when the sensing capacitor is changed, an output voltage outputted by the output terminal of the operational amplifier is also changed accordingly.

12. The capacitive touch sensing circuit of claim 11, wherein in a first charge-transfer phase, an output voltage change amount of the output voltage is related to a sensing capacitance change amount of the sensing capacitor, the sensing capacitor, the series capacitor, the parallel capacitor and a first voltage of the first node.

13. The capacitive touch sensing circuit of claim 12, wherein a ratio of the first voltage to the reference voltage is related to a ratio of the test capacitor to the series capacitor.

14. The capacitive touch sensing circuit of claim 11, wherein in a second charge-transfer phase, an output voltage change amount of the output voltage is related to a sensing capacitance change amount of the sensing capacitor, the sensing capacitor, the series capacitor, the parallel capacitor and a voltage value obtained by subtracting a second voltage of the first node from the operating voltage.

15. The capacitive touch sensing circuit of claim 14, wherein a ratio of the voltage value subtracting the second voltage from the operating voltage to the reference voltage is related to a ratio of the test capacitor to the series capacitor.
